(19) United States
(12) Patent Application Publication
(10) Pub. No.: US 2007/0201262 A1
(43) Pub. Date: Aug. 30, 2007

(54) Logic SRAM cell with improved stability

(75) Inventors: Rajiv V. Joshi, Yorktown Heights, NY (US); Leland Chang, New York, NY (US)

Correspondence Address: HOFFMAN, WARNICK & D'ALESSANDRO LLC, 75 State Street, 14th Floor, ALBANY, NY, 12207, US

(73) Assignee: International Business Machines Corporation, Armonk, NY (US)

(21) Appl. No.: 11/363,311

(22) Filed: Feb. 27, 2006

(51) Int. Cl. G11C 11/00

(52) U.S. Cl. 365/154

(57) ABSTRACT

A static random access memory (SRAM) cell with improved stability that can handle half select operations. The disclosed cell includes: a pair of cross-coupled inverters coupled to a write bit line via a pass transistor, the pass transistor including a gate coupled to a pseudo write word line; a pair of serially coupled transistors coupled to a read bit line, a gate of a first serially coupled transistor being coupled to a read word line and a gate of a second serially coupled transistor being coupled to the pair of cross-coupled inverters; and a word line driver having an output coupled to the pseudo write word line and an input coupled to a write word line, the word line driver being controllable by a bit select input.

### FIELD OF THE INVENTION

The present invention relates to data storage, and more specifically to an SRAM storage cell that includes separate word and bit lines for simultaneous read/write operations, and which can support half select operations.

### BACKGROUND OF THE INVENTION

Many different types of data storage are used in various parts of a computer system. Non-volatile memory retains its data even when power is not applied. Volatile memory requires energy to retain its data. Two types of volatile memory are static and dynamic random-access memory (RAM).

SRAM (Static Random Access Memory) devices are well known in the art. A typical SRAM device comprises an array of memory cells with each SRAM cell containing a binary digit (bit) of data. An SRAM cell holds the data in a latch. The latch holds the bit information so long as power is supplied to the cell. Since an SRAM cell can hold the data information indefinitely so long as power is supplied thereto, it can be interrogated either by read or write, at any time.

Conventional SRAM arrays include SRAM cells arranged in rows and columns, and addressing circuitry that accesses a selected row of SRAM cells using address data corresponding to the physical address of the SRAM cells. That is, data words stored in the rows of conventional SRAM cells are accessed by applying address signals to the SRAM array input terminals. In response to each unique set of address signals, an SRAM array outputs a data word that is read from a group of SRAM cells designated by the address.

The standard CMOS SRAM cell uses a pair of cross-coupled CMOS inverters, having two N-channel and two P-channel transistors. Such cells are known as 6-T cells, since (with the two pass transistors) they have six transistors per cell. FIG. 1 depicts a prior art cell 10 that includes a standard SRAM cell having a pair of cross coupled inverters 26, and a pair of pass transistors 22 and 24. Also included (shown in dotted lines) are separate read word (RWL) 18 and read bit (RBL) 20 lines, along with a serially coupled pair of FETs 28, to allow for simultaneous read/write operations. Thus, the resulting cell 10 includes a separate write word line (WWL) 12, write bit line (WBL) 14 and inverted write bit line ( W̅B̅L̅)16. The result is an 8-T cell 10 that includes a separate read mechanism, which eliminates both read disturbs and write disturbs since there is no sharing of the write word line.

Unfortunately, the 8-T cell 10 shown in FIG. 1 does not support a half select operation. A half select operation occurs, e.g., when WWL 12 is selected and WBL 14 is not selected. When this condition happens in the context of a memory array, all bit lines in the row will be exposed to the charge on WBL 14. Thus, these half select charges can affect and corrupt data stored in adjacent cells.

Accordingly, a need exists for an SRAM that will support half select operations and separate read/write operations.

### SUMMARY OF THE INVENTION

The present invention addresses the above-mentioned problems, as well as others, by providing an eight transistor (8-T) SRAM cell having an additional bit select control coupled to the write word line. The resulting structure includes all of the features of the cell shown in FIG. 1, but in addition supports half select operations, allows multi-bit soft error rate (SER) protection since a column select is allowed, and provides better rise and fall characteristics on the write word line.

In a first aspect, the invention provides a static random access memory (SRAM) cell, comprising: a pair of cross-coupled inverters coupled to a write bit line via a pass transistor, the pass transistor including a gate coupled to a pseudo write word line; a pair of serially coupled transistors coupled to a read bit line, a gate of a first serially coupled transistor being coupled to a read word line and a gate of a second serially coupled transistor being coupled to the pair of cross-coupled inverters; and a word line driver having an output coupled to the pseudo write word line and an input coupled to a write word line, the word line driver being controllable by a bit select input.

In a second aspect, the invention provides a static random access memory (SRAM) array comprising: an array of cells arranged into sets, each set including an associated pseudo write word line, and each cell in a set including a pair of cross-coupled inverters coupled to a write bit line via a pass transistor, the pass transistor including a gate coupled to the associated pseudo write word line, and a pair of serially coupled transistors coupled to a read bit line, a gate of a first serially coupled transistor being coupled to a read word line and a gate of a second serially coupled transistor being coupled to the pair of cross-coupled inverters; and a plurality of word line drivers, each word line driver controlling a unique set of cells and including an output coupled to a pseudo write word line associated with the unique set of cells and an input coupled to a write word line, and each word line driver being controllable by a different bit select input.

In a third aspect, the invention provides a word line driver for controlling an input to a static random access memory (SRAM) device, the word line driver including a logical AND gate having inputs coupled to a write word line and a bit select line, and an output coupled to a pseudo write word line associated with the SRAM device.

In a fourth aspect, the invention provides a method of performing a half select operation in a static random access memory (SRAM) array, comprising: providing an array of cells, each cell including: a pair of cross-coupled inverters coupled to a write bit line via a pass transistor, the pass transistor including a gate coupled to a pseudo write word line; a pair of serially coupled transistors coupled to a read bit line, a gate of a first serially coupled transistor being coupled to a read word line and a gate of a second serially coupled transistor being coupled to the pair of cross-coupled inverters; and a word line driver having an output coupled to the pseudo write word line and an input coupled to a write word line, the word line driver being controllable by a bit select input; turning the write word line off; setting the write bit line high; and setting the bit select input to low to drive the pseudo write word line low or 0 volts.

In each of the above aspects, the invention may be implemented in an integrated circuit that includes other functions and circuitry not specifically described herein.

### BRIEF DESCRIPTION OF THE DRAWINGS

These and other features of this invention will be more readily understood from the following detailed description of the various aspects of the invention taken in conjunction with the accompanying drawings in which:

FIG. 1 depicts a prior art 8-T SRAM cell.

FIG. 2 depicts an SRAM cell having a word line driver in accordance with the present invention.

FIG. 3 depicts a portion of a memory array in which sets of SRAM cells are controlled by associated word line drivers in accordance with the present invention.

### DETAILED DESCRIPTION OF THE INVENTION

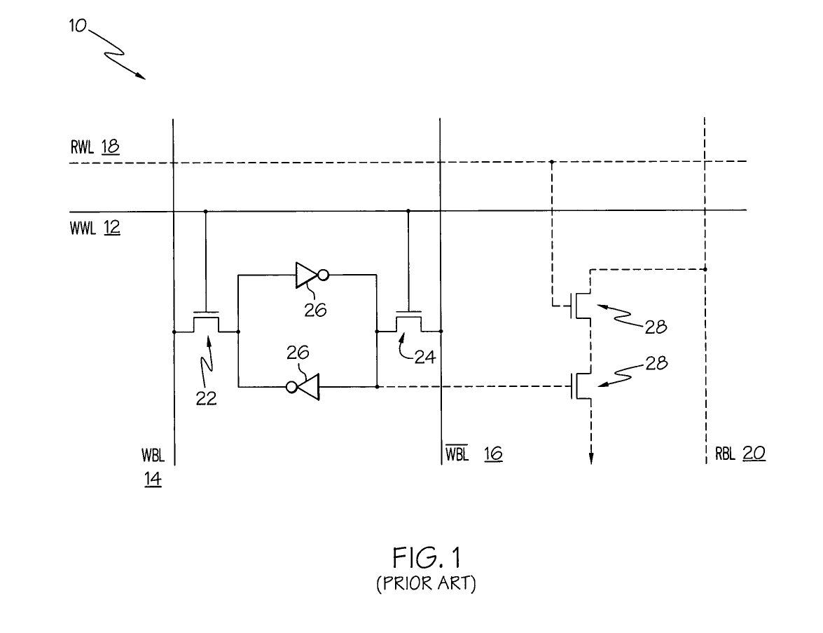

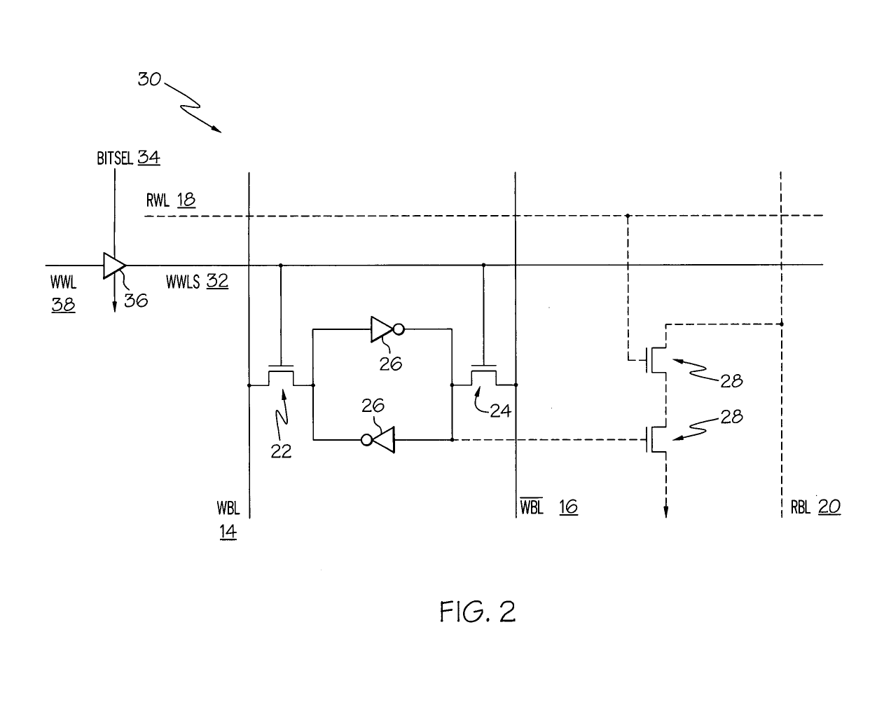

Referring now to drawings, FIG. 2 depicts an SRAM logic cell 30 that includes essentially the same circuit as that shown in FIG. 1, but includes a word line driver 36 that is controlled by a bit select input 34, “BITSEL.” Thus, the write word line WWL 38 is coupled to an input of the word line driver 36, which can be turned on or off by the bit select input 34. The output of the word line driver 36, referred to herein as the pseudo word line “WWLS” 32, is then coupled to the pass transistors 22, 24 of the memory cell. Word line driver 36 may be implemented, for instance, with an AND gate such that the pseudo word line 32 can be driven low by the bit select input 34 whenever the write word line 38 is not selected. As is well known in the art, a logical AND gate may be implemented as a pair of serially coupled FETs. It should also be understood that bit select input 34 may be driven by any signal and/or logic that will allow the SRAM logic cell 30 to perform a half select operation (e.g., it may be driven by a column bit line).

In the embodiment shown in FIG. 2, the word line driver 36 is contained within each cell 30, such that each cell 30 can be controlled by a separate bit select input. However, it should be understood that the word line driver 36 may be implemented to control a single memory device or a set of memory devices. In the case where word line driver 36 controls a set of memory devices (e.g., an array of cells), word line driver 36 may be implemented as a logical AND gate that includes inputs coupled to a write word line and a bit select line, and an output coupled to a pseudo write word line. Thus, the pseudo write word line may control a single memory device or a set of memory devices. Also note that word line driver 36 may be implemented using any type of logic device (e.g., OR, NOR, NAND, etc.), and is not limited to a logical AND gate.

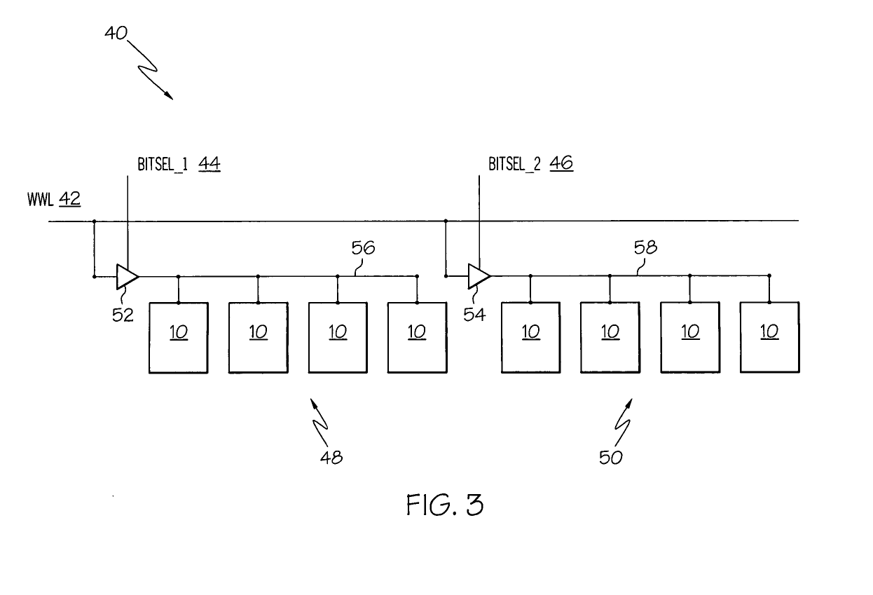

FIG. 3 illustrates an example in which multiple word line drivers (52, 54) each control a set of memory cells (48, 50). Thus, different sets of cells (48, 50) in a memory array, e.g., made up of the 8-T SRAM cells 10 shown in FIG. 1, are controlled by different word line drivers (52, 54). In this illustrative embodiment, a first set 48 of four cells 10 are associated with and controlled by a first word line driver 52 based on a first bit select input “BITSEL_{—}1” 44, and a second set 50 of four cells 10 are associated with and controlled by a second word line driver 54 based on a second bit select input “BITSEL_{—}2” 46. Thus, the first word line driver 52 includes an input coupled to WWL 42 and an output coupled to a first pseudo write word line 56, and the second word line driver 54 includes an input coupled to WWL 42 and an output coupled to a second pseudo write word line 58. Obviously, the number and location of cells in each set, the arrangement of the word line drivers, array configuration, pseudo write word lines, etc., can vary depending on the particular application.

The foregoing description of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of this invention as defined by the accompanying claims.

1. A static random access memory (SRAM) cell, comprising:
a pair of cross-coupled inverters coupled to a write bit line via a pass transistor, the pass transistor including a gate coupled to a pseudo write word line;
a pair of serially coupled transistors coupled to a read bit line, a gate of a first serially coupled transistor being coupled to a read word line and a gate of a second serially coupled transistor being coupled to the pair of cross-coupled inverters; and
a word line driver having an output coupled to the pseudo write word line and an input coupled to a write word line, the word line driver being controllable by a bit select input.

2. The SRAM cell of claim 1, the pair of cross-coupled inverters being further coupled to an inverted write bit line via a second pass transistor.

3. The SRAM cell of claim 1, the word line driver being comprised of an AND gate.

4. The SRAM cell of claim 1, the pair of cross-coupled inverters comprising two N-channel and two P-channel transistors.

5. The SRAM cell of claim 1, the pair of serially coupled transistors being further coupled to a ground voltage.

6. The SRAM cell of claim 1, being implemented in an integrated circuit.

7. A static random access memory (SRAM) array comprising:
an array of cells arranged into sets, each set including an associated pseudo write word line, and each cell in a set including a pair of cross-coupled inverters coupled to a write bit line via a pass transistor, the pass transistor including a gate coupled to the associated pseudo write word line, and a pair of serially coupled transistors coupled to a read bit line, a gate of a first serially coupled transistor being coupled to a read word line and a gate of a second serially coupled transistor being coupled to the pair of cross-coupled inverters; and
a plurality of word line drivers, each word line driver controlling a unique set of cells and including an output coupled to a pseudo write word line associated with the unique set of cells and an input coupled to a write word line, and each word line driver being controllable by a different bit select input.

8. The SRAM array of claim 7, the pair of cross-coupled inverters being further coupled to an inverted write bit line via a second pass transistor.

9. The SRAM array of claim 7, each word line driver comprising an AND gate.

10. The SRAM array of claim 7, the pair of cross-coupled inverters comprising two N-channel and two P-channel transistors.

11. The SRAM array of claim 7, the pair of serially coupled transistors being further coupled to a ground voltage.

12. The SRAM array of claim 7, being implemented in an integrated circuit.

13. A word line driver for controlling an input to a static random access memory (SRAM) device, the word line driver including a logical AND gate having inputs coupled to a write word line and a bit select line, and an output coupled to a pseudo write word line associated with the SRAM device.

14. The word line driver of claim 13, the SRAM device comprising a memory cell.

15. The word line driver of claim 14, the memory cell including:
a pair of cross-coupled inverters coupled to a write bit line via a pass transistor, the pass transistor including a gate coupled to the pseudo write word line; and
a pair of serially coupled transistors coupled to a read bit line, a gate of a first serially coupled transistor being coupled to a read word line and a gate of a second serially coupled transistor being coupled to the pair of cross-coupled inverters.

16. The word line driver of claim 15, the pair of cross-coupled inverters being further coupled to an inverted write bit line via a second pass transistor.

17. The word line driver of claim 15, the pair of cross-coupled inverters comprising two N-channel and two P-channel transistors.

18. The word line driver of claim 15, the pair of serially coupled transistors being further coupled to a ground voltage.

19. The word line driver of claim 13, the SRAM device comprising an array of memory cells.

20. The word line driver of claim 13, being implemented in an integrated circuit.
